(19) United States
(12) Patent Application Publication
(10) Pub. No.: US 2009/0230979 A1
(43) Pub. Date: Sep. 17, 2009

(54) FULLERENE OR NANOTUBE, AND METHOD FOR PRODUCING FULLERENE OR NANOTUBE

(75) Inventors: Kenji Omote, Miyagi (JP); Yuzo Mizobuchi, Miyagi (JP); Yasuhiko Kasama, Miyagi (JP)

Correspondence Address: YOUNG & THOMPSON, 209 Madison Street, Suite 500, ALEXANDRIA, VA, 22314, US

(73) Assignee: IDEAL STAR INC., Sendai-shi, Miyagi (JP)

(21) Appl. No.: 12/065,738

(22) PCT Filed: Sep. 5, 2006
(86) PCT No.: PCT/JP2006/317526

§ 371 Date: Apr. 8, 2008

(30) Foreign Application Priority Data
Sep. 5, 2005 (JP) 2005-256900
Apr. 27, 2006 (JP) 2006-123976

(51) Int. Cl. G01R 27/08; C01B 31/02; B05D 5/12; D01F 9/12; B32B 9/00; B32B 15/04; B01J 19/00

(52) U.S. Cl. 324/693; 423/445 B; 427/122; 423/447.2; 423/447.7; 428/408; 422/198; 977/734; 977/742

(57) ABSTRACT

Fullerenes are a novel material that has been expected to serve as a promising material in the construction of organic devices. However, the electric conductivity of fullerenes, which has been, reported heretofore spreads over a wide range including values corresponding to insulators as well as those corresponding to semiconductors. The present invention makes it possible to improve the conductivity of fullerenes highly reproducibly by heating the fullerenes at a specified temperature in an inert gas which is flowed under a specified condition, that is, by controlling the concentration of impurities, particularly oxygen and water adsorbed to the fullerenes.

### TECHNICAL FIELD

This invention relates to a method of producing fullerenes or a nanotube, and a method of producing a device using fullerenes or a nanotube.

### BACKGROUND ART

[Non-Patent Document 1] “Chemistry and Physics of Fullerenes,” H. Shinohara and Y. Saito, p. 134

[Non-Patent Document 2] J. Mort et al., Appl. Phys. Lett. 60(14), 1735 (1992)

[Non-Patent Document 3] T. Arai et al., Solid State Communications, Vol. 84, No. 8, 827 (1992)

[Non-Patent Document 4] T. Unold et al., Synthesis Metals 121 (2001) 1179-1180

[Non-Patent Document 5] A. Hamed et al., Physical Review B, Vol. 47, No. 16, 10873 (1993)

[Non-Patent Document 6] Photoelectric Properties and Applications of Low-Mobility Semiconductors, R. Konenkamp, Springer, p. 65

Fullerenes are spherical carbon molecules represented by Cn (n=60, 70, 78, 84, . . . ), and a third carbon isoform next to diamond and graphite. The method enabling the mass production of fullerenes was established in 1990, and since that time researches on fullerenes have been vigorously pursued.

Studies on the electric conductivity of fullerenes have been reported by a number of researchers. FIG. 10 is a graph representing, for comparison, the electric conductivities of C₆₀ published previously. In the same figure, the data marked by Mort, Arai, Unold, Hamed, and Konenkamp represent the electric conductivities of C₆₀ molecules reported in the non-patent documents 2 to 6, respectively. From the figure, it is seen that the electric conductivity of fullerenes heavily depends on the degree of vacuum of the measurement environment, and that the conductivity of fullerenes tends to become higher as the measurement environment is more strongly evacuated. The “In Situ” measurement in the figure means a measurement where a fullerene film is formed in vacuum by vapor deposition and the film measured of its conductivity at the site without being removed from the vacuum vessel. A tendency is recognized from the inspection of the figure: when the degree of vacuum is high, that is, in terms of pressure lower than about 10⁻⁸ Torr, fullerenes exhibit a conductivity of equal to or higher than 10⁻⁶ (Ωcm)⁻¹, and when the degree of vacuum is poor, or in terms of pressure higher than about 10⁻⁷ Torr, fullerenes exhibit a conductivity lower than 10⁻⁶ (Ωcm)⁻¹. It has been generally accepted that a material whose conductivity is equal to or higher than 10⁻⁶ (Ωcm)⁻¹ corresponds to a semiconductor while a material whose conductivity is less than 10⁻⁶ (Ωcm)⁻¹ corresponds to an insulator.

The fullerene is a novel substance with a singular electron state which results from the spreading of n electrons over the entire expanse of the spherical molecule, and it has been expected that it will exhibit excellent properties when applied in the manufacture of devices such as transistors, solar batteries, fuel cells, indicator apparatuses, sensors, or the like, particularly when used as a material in the manufacture of organic devices. When fullerenes are used as a material in the manufacture of a device, it will be desirable for the fullerenes to have a conductivity falling within the range of semiconductors (equal to or higher than 10⁻⁶ (Ωcm)⁻¹). In particular, when fullerenes are used as a material in the manufacture of a high performance device working at a high speed and little loss, it will be desirable for the fullerenes to have a high conductivity.

However, as described above, the previously reported conductivities of fullerenes spread over a wide range including those corresponding to insulators as well as semiconductors. It has been reported that a major factor responsible for the lowered conductivity of fullerenes is the adsorption of oxygen to the fullerenes. In fact, when fullerenes are kept in an oxygen-containing atmosphere, oxygen will be adsorbed (physical adsorption) to the fullerenes during the crystallization of the latter, and the conductivity of the fullerenes will be greatly lowered as compared with corresponding fullerenes which have not been exposed to oxygen. For example, it has been reported that, when fullerenes have been exposed to oxygen, its conductivity lowers to a level one ten-thousandth of the conductivity the same fullerenes would exhibit at In Situ measurement. When oxygen is adsorbed to fullerenes where electrons serve as dominant charge carriers, the oxygen will be negatively charged, and serve as an acceptor to thereby reduce the density of conductive electrons, and lower the conductivity of the fullerenes (non-patent document 3). Even in the case of In Situ measurement, when the measurement is performed in poor vacuum level, fullerenes will not have a high conductivity (non-patent document 4). This is probably ascribed to the existence of a tiny amount of oxygen in the evacuated vessel which is adsorbed to the fullerenes and lowers their conductivity.

Studies also have been performed on the change in electric conductivity of fullerenes, which have been kept in an atmosphere of an inert gas at room temperature, and results reported. According to non-patent document 3, fullerenes, which had been kept in a nitrogen atmosphere, was found to have a conductivity higher by several % than corresponding fullerenes kept in vacuum. Non-patent document 5 reports that when C₆₀ molecules are kept in an atmosphere full of Ar, N₂ or He at 21° C., their conductivity remains invariable. This is probably because an inert gas, even when it is adsorbed to fullerenes, will not act as a factor lowering the electric conductivity of the fullerenes.

No studies have been performed heretofore on the effect of other impurities than oxygen and inert gases on the electric conductivity of fullerenes. In addition, with regard to the effect of oxygen and inert gases on fullerenes, the relationship of the concentration of an adsorbed impurity with the change in electric conductivity of fullerenes has never been studied.

On the other hand, there is a study, which reports a method for recovering the conductivity of fullerenes to which oxygen has been adsorbed. According to non-patent documents 3, 5, and 6, it is possible to recover the conductivity of fullerenes to which oxygen has been adsorbed, by heating the fullerenes in vacuum. Furthermore, non-patent document 1 gives a description stating that it is possible to remove the majority of adsorbed oxygen by heating the fullerenes at a temperature equal to or higher than 180° C. in vacuum or in an inert gas atmosphere.

Physical adsorption of oxygen is a reversible phenomenon. It is possible to remove oxygen adsorbed to fullerenes by heating the fullerenes in vacuum or in an inert atmosphere. This is in contrast with a case in which fullerenes have been heated or irradiated with light in an oxygen-containing atmosphere where the conductivity of the fullerenes is lowered. In the latter case, oxygen binds chemically to the carbon atoms of the fullerenes, and thus it is not possible to remove the oxygen by heating the fullerenes in vacuum or in an inert atmosphere.

### DISCLOSURE OF THE INVENTION

A known method for recovering the electric conductivity of fullerenes includes heating the fullerenes in vacuum. However, when the manufacture of an organic device is involved, it may include a process, which rejects the use of an evacuating machine. For example, a process of applying, by coating, an organic material on the surface of a device should be done at a normal atmospheric pressure.

The present inventors, in an attempt to find a method for recovering or improving the conductivity of fullerenes by purging oxygen once adsorbed to the fullerenes without resorting to vacuum, used heating in a similar condition to that employed by non-patent document 1. Specifically, according to one trial method, using a heated atmosphere, which consists of purged nitrogen, performed heating at 200° C. However, this method did not give a notable result: the conductivity of fullerenes which had lowered to 10⁻⁹ (Ωcm)⁻¹ recovered only up to 10⁻⁸ (Ωcm)⁻¹. Namely, as long as dependent on the knowledge derived from non-patent document 1, it was impossible to recover the conductivity to a level equal to or higher than 10⁻⁸ (Ωcm)⁻¹.

The highest known conductivity of fullerenes up to the present is the one reported in non-patent document 6 that is equal to 10⁻² (Ωcm)⁻¹. Thus, there have been no such excellent fullerenes in this world as to have a conductivity equal to or higher than 10⁻¹ (Ωcm)⁻¹.

### Means for Solving Problem

A first aspect of the present invention relates to fullerenes, which contain oxygen at 10¹⁴ molecules/cm³ or less, and water at 10¹⁶ molecules/cm⁻³ or less.

A second aspect of the present invention relates to fullerenes, which contain water at 10¹⁶ molecules/cm³ or less.

A third aspect of the present invention relates to fullerenes, which have an electric conductivity of 10⁻¹ (Ωcm)⁻¹ or higher, and 10 (Ωcm)⁻¹ or lower when measured at 27° C.

A fourth aspect of the present invention relates to fullerenes, which have an electric conductivity of 10⁻¹ (Ωcm)⁻¹ or higher, and 10³ (Ωcm)⁻¹ or lower when measured at 27° C.

A fifth aspect of the present invention relates to fullerenes as described in aspects (1) to (4) which are either C₆₀, C₇₀, C₇₆, C₇₈, C₈₂, or C₈₄, or a mixture thereof.

A sixth aspect of the present invention relates to a nanotube which contains oxygen at 10¹⁴ molecules/cm³ or less, and water at 10¹⁶ molecules/cm³ or less.

A seventh aspect of the present invention relates to a nanotube, which contains water at 10¹⁶ molecules/cm³ or less.

An eighth aspect of the present invention relates to a solid body, powder, coating membrane, single crystal, poly-crystal, film, fiber, dopant material, vapor-deposited material, or co-deposited material which contains fullerenes as described in aspects (1) to (5), or a nanotube as described in aspects (6) or (7).

A ninth aspect of the present invention relates to a transistor, solar battery, fuel cell, organic EL, sensor, or resistance which incorporates fullerenes as described in aspects (1) to (5), or a nanotube as described in aspects (6) or (7).

A tenth aspect of the present invention relates to a method of producing fullerenes or a nanotube which comprises heating fullerenes as described in aspects (1) to (5), or a nanotube as described in aspects (6) or (7) at a temperature not lower than 200° C. and not higher than 700° C. in an inert gas for a period not shorter than 10 seconds and not longer than 10 hours.

An eleventh aspect of the present invention relates to a method of producing fullerenes or a nanotube which comprises heating fullerenes as described in aspects (1) to (5), or a nanotube as described in aspects (6) or (7) at a temperature not lower than 100° C. and not higher than 700° C. for a period not shorter than 10 seconds and not longer than 10 hours in an inert gas within a vessel while the inert gas is being purged from the vessel.

A twelfth aspect of the present invention relates to a method of producing fullerenes or a nanotube which comprises heating fullerenes or a nanotube at a temperature not lower than 100° C. and not higher than 700° C. for a period not shorter than 10 seconds and not longer than 10 hours in an inert gas within a vessel having a volume of V liter while the inert gas is being continuously flowed at a rate not lower than 3V liter/min and not higher than 10V liter/min.

A thirteenth aspect of the present invention relates to a method of producing fullerenes or a nanotube which comprises heating fullerenes or a nanotube at a temperature not lower than 100° C. and not higher than 700° C. for a period not shorter than 10 seconds and not longer than 10 hours while the heating is allowed to proceed at a rate not higher than 20° C./min.

A fourteenth aspect of the present invention relates to a method of producing fullerenes or a nanotube as described in aspects (10) to (13), wherein the fullerenes are C₆₀, C₇₀, C₇₆, C₇₈, C₈₂, or C₈₄, or a mixture thereof.

A fifteenth aspect of the present invention relates to a method of producing fullerenes or a nanotube as described in aspects (10) to (14), wherein the inert gas comprises a gas selected from the group comprising pure nitrogen, Ar, He, Kr, Ne, and Xe, and a mixture thereof.

A sixteenth aspect of the present invention relates to a method of producing fullerenes or a nanotube as described in aspects (10) to (15), wherein the inert gas environment in contact with the fullerenes or the nanotube contains oxygen at 10 ppb or lower, and water at 10 ppb or lower.

A seventeenth aspect of the present invention relates to a method of producing fullerenes or a nanotube as described in aspects (10) to (16), wherein the vessel or the tube through which an inert gas is introduced into the vessel has an internal wall made of a stainless steel material which receives, on its surface, the protective coating of a passivity membrane made of chromium oxide, aluminum oxide or metal fluoride.

An eighteenth aspect of the present invention relates to a method of producing fullerenes or a nanotube as described in aspects (10) to (17), wherein the vessel or the tube through which an inert gas is introduced into the vessel is made of a material which releases gas from its surface at a rate not higher than 1×10⁻¹⁵ (Torr*1/sec*cm²)

A nineteenth aspect of the present invention relates to a method of producing an organic device which comprises preparing a film made of fullerenes or a nanotube produced by a method as described in aspects (10) to (18), and forming a protective film made of SiO₂, Si₃N₄, polyimide, polymethylmethacrylate, polyvinylidenefluoride, polycarbonate, polyvinylalcohol, acryl resin or glass by CVD, PVD, spin coating, spray coating, or dip coating.

A twentieth aspect of the present invention relates to a deposited film made of fullerenes or a nanotube which is deposited, using fullerenes having a carbon content not lower than 99.6 wt %, in a vacuum having a degree of vacuum not higher than 10⁻⁹ Torr within a vacuum vessel which has an internal wall made of a stainless steel material receiving, on its surface, the protective coating of a passivity membrane made of chromium oxide, aluminum oxide or metal fluoride.

A twenty-first aspect of the present invention relates to a deposited film made of fullerenes or a nanotube which is deposited, using fullerenes having a carbon content not lower than 99.6 wt %, in a vacuum having a degree of vacuum not higher than 10⁻¹¹ Torr within a vacuum vessel with an internal wall which releases gas from its surface at a rate not higher than 1×10⁻¹⁵ (Torr*1/sec*cm²).

A twenty-second aspect of the present invention relates to a method of producing a deposited film made of fullerenes or a nanotube which comprises using fullerenes having a carbon content not lower than 99.6 wt %, and depositing the film in a vacuum having a degree of vacuum not higher than 10⁻⁹ Torr within a vacuum vessel with an internal wall made of a stainless steel material which receives, on its surface, the protective coating of a passivity membrane made of chromium oxide, aluminum oxide or metal fluoride.

A twenty-third aspect of the present invention relates to a method of producing a deposited film made of fullerenes or a nanotube which comprises using fullerenes having a carbon content not lower than 99.6 wt %, and depositing the film in a vacuum having a degree of vacuum not higher than 10⁻¹¹ Torr within a vacuum vessel having an internal wall which releases gas from its surface at a rate not higher than 1×10⁻¹⁵ (Torr*1/sec*cm²).

A twenty-fourth aspect of the present invention relates to a system for producing fullerenes or a nanotube which comprises a vessel equipped with a gas inflow port and a gas outflow port, a heating means, a heating control means, and a gas flow control means and which can control both the heating condition and the gas flow condition in association.

A twenty-fifth aspect of the present invention relates to a gas sensor using, as a sensor body, fullerenes as described in aspects (1) to (5), or a nanotube as described in aspect (6) or (7).

A twenty-sixth aspect of the present invention relates to a gas detection method for checking the presence a gas or determining its concentration by monitoring the change in resistance of fullerenes as described in aspects (1) to (5), or of a nanotube as described in aspect (6) or (7).

### Effect of the Invention

According to the above aspects of the present invention, following advantages will be ensured.

1. It will be possible to recover or improve the conductivity of fullerenes or a nanotube even at a normal atmospheric pressure. The inventive method can be safely applied to a process necessary for the manufacture of an organic device, which is normally incompatible with treatment in vacuum.

2. The inventive method will not require the use of an expensive evacuation machine, and thus the production cost will be reduced.

3. The inventive method will make it possible to efficiently remove oxygen contained in fullerenes or in a nanotube, and thus to securely recover or improve the conductivity of the fullerenes or the nanotube.

4. Since according to the inventive method, it is possible to remove not only oxygen but also water contained in fullerenes or in a nanotube, it will be possible to manufacture fullerenes having a high conductivity, for example, 10⁻¹ (Ωcm)⁻¹ or higher.

5. Since according to the inventive method, it is possible to manufacture organic semiconductor materials having a high conductivity. So it will be possible to produce organic devices such as high performance transistors, solar batteries, fuel cells, organic EL's, and sensors. The organic devices have equal in performance to inorganic semiconductor devices.

6. Since it is possible to alter the conductivity of given fullerenes or a given nanotube by adjusting the concentration of impurities therein, it will be possible to utilize the concentration of impurities for the high precision manufacture of fullerenes or a nanotube having a desired conductivity, for example the conductivity can be controlled 10⁻⁹ (Ωcm)⁻¹ or more and 10³ (Ωcm)⁻¹ or less. It will be also possible to allow a small element having a small area to have a high resistance.

7. Since a material containing fullerenes or a nanotube of the invention greatly changes its resistance according to the concentration of oxygen or water contained in a gas in contact with the material, it will be possible to use the material as a sensor such as a gas sensor.

### BRIEF DESCRIPTION OF THE DRAWINGS

FIG. 1 gives the outline of a treatment system where vapor deposition and heating of an inert gas are performed continuously.

FIG. 2 shows a graph representing the change in conductivity of fullerenes when the inventive nitrogen heating treatment is applied to the fullerenes.

FIG. 3 shows a graph representing the change in conductivity of fullerenes when the inventive argon heating treatment is applied to the fullerenes.

FIG. 4 represent the concentration data of impurities detected with an API mass spectroscopy apparatus.

FIG. 5 represent the concentration data of impurities detected with the API mass spectroscopy apparatus.

FIGS. 6(a) to 6(h) are a collection of diagrams for explaining the adsorption and dissociation of impurities to and from fullerenes.

FIG. 7 shows the data representing the correlation of the conductivity of C₆₀ with the concentration of impurities therein.

FIG. 8 shows the data representing the correlation of the conductivity of C₆₀ with the concentration of impurities therein.

FIG. 9 shows the change in conductivity of fullerenes when the fullerenes receive the coating of a protective membrane on its surface according to the invention.

FIG. 10 is a graph representing, for comparison, the electric conductivities of fullerenes published previously.

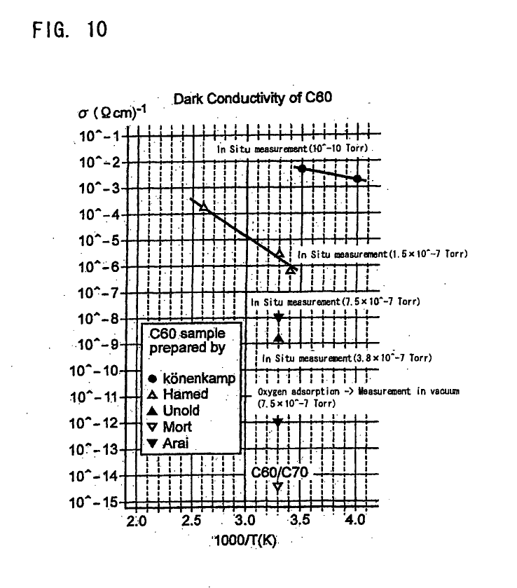

FIGS. 11(a) and 11(b) show the sectional views of illustrative gas sensors representing the embodiments of the present invention.

FIG. 12 shows a graph representing the dependency of the recovery of lowered conductivity of fullerenes due to heating treatment on the flow rate of inert gas.

### REFERENCE NUMERALS

1. Vessel
2. Vacuum pump
3. Gas inflow tube
4. Gas outflow tube
5. Heater for fullerene sublimation
6. Crucible
7. Fullerene powder
8. Vapor deposition substrate
9. Fullerene film
10. Heater for heating substrate
21, 31. Test gas
22, 23, 32. Inflow tube of test gas
24, 25. Inflow tube of nitrogen gas
26, 27, 38. Film comprising fullerenes
28, 29, 33. Heater
30, 39. Electric resistance measuring meter
34. Gas flow
35. Power source for applying high voltage
36. Gas ions
37. Grid electrode

### BEST MODE FOR CARRYING OUT THE INVENTION

The best embodiments for carrying out the invention will be described below.

The present inventors made a detailed survey on the effect of various impurities contained in fullerenes on the electric conductivity of the latter, and the change in conductivity of the latter when the heating condition of an inert gas in contact with the fullerenes is altered. In particular, they quantitatively evaluated the concentration of impurities adsorbed to the fullerenes, and investigated the relationship of the quantity data with the conductivity of the fullerenes.

As a result, it was found that water adsorbed to fullerenes have a great effect on the conductivity of the fullerenes. This is a very important observation that has never been predicted from the knowledge obtained from previous references. Non-patent document 5 gives a description stating, “it has been known that water vapor acts as a catalyst for promoting the oxidation of certain substances. However, it has never been known that water vapor has any effect on the conductivity of fullerenes.” No one could predict from this description of non-patent document 5 that adsorption of water to fullerenes will lower the conductivity of the fullerenes. Except for non-patent document 5, there is no known document that suggests the possible effect of water adsorbed to fullerenes on the conductivity of the fullerenes.

Furthermore, the present inventors discovered that it is possible to efficiently remove water adsorbed to fullerenes under a specified heating condition and to greatly improve the conductivity of the fullerenes. They also succeeded in efficiently removing oxygen adsorbed to fullerenes by altering the heating condition.

They made it possible to produce fullerenes having a high conductivity that has never been observed in this world up to the present, by using an inert gas having a high purity and heating that inert gas, thereby lowering the concentrations of oxygen and water contained in the fullerenes to levels not higher than 10¹⁴ cm⁻³ and 10¹⁶ cm⁻³, respectively.

They also found that, when a fullerene film which has undergone a heating treatment in the presence of such an inert gas, has a passivation film deposited thereon, that layered film will exhibit no lowered conductivity even when it is placed in the normal atmosphere or in an oxygen atmosphere.

(Preparation of Test Samples and Measurement of Their Conductivity)

Before the heating treatment according to the invention is described, description will be given about how fullerene test samples used for the conductivity measurement were prepared and the method whereby the conductivity of the test samples was measured.

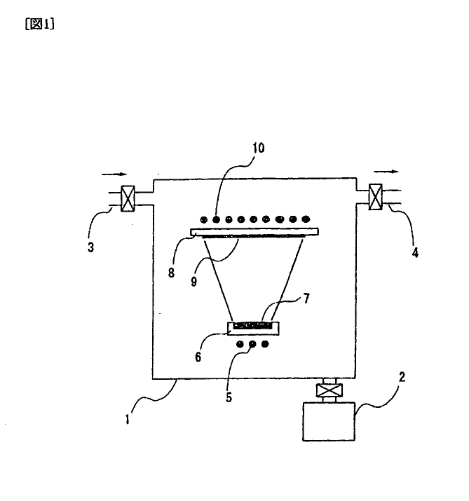

FIG. 1 gives the outline of a treatment system wherewith vapor deposition and heating of an inert gas are performed continuously. The treatment system shown in the figure is composed of a vessel 1, vacuum pump 2, gas inflow tube 3, gas outflow tube 4, crucible 6, vapor deposition substrate 8, and substrate heater 10. The vapor deposition substrate 8 for conductivity measurement is obtained by forming gold electrodes in advance on a glass substrate. The electrodes are connected via leads to a testing meter placed outside the treatment system so that on completion of the treatment process, the electric property of a test sample can be evaluated at the site without requiring the removal of substrate 8 from vessel 1.

The system shown in FIG. 1 is a system used for both of the vapor deposition and inert gas heating. However, an alternative heating treatment system may be employed according to the invention which consists of a vessel 1, gas inflow tube 3, gas outflow tube 4, and substrate heater 10, and a fullerene film holder, that is, a system devoid of elements necessary for vapor deposition. In this case, the fullerene film holder will be positioned in place of the vapor deposition substrate 8.

First, a vapor deposition substrate 10 is mounted in place within vessel 1; fullerene powder 7 is transferred into crucible 6; valves attached to gas inflow tube 3 and gas outflow tube 4 are closed; and the vacuum pump 2 is activated to evacuate the vessel 1. Next, electric current is passed through the fullerene sublimating heater 5 to heat the crucible 6 to sublimate the fullerene powder 7.

For the experiment, a fullerene powder with a purity of 99.8% was used, and vapor deposition occurred in vacuum whose pressure is 1.0 to 5.0×10⁻⁷ Torr. Crucible 6 was heated to 500° C., to allow fullerenes to sublimate for 2 hours. This sublimation process caused a fullerene film with a flat top surface having a thickness of about 0.8 μm to be deposited on a vapor deposition substrate 8.

Measurement of the conductivity of a test sample during vapor deposition (As Depo measurement) occurs under a condition as described above. The measurement temperature is controlled by the substrate heater 10, and a cooling unit and thermal sensor both of which are not illustrated here. In this experiment, the conductivity of a test sample was measured via two terminals. Two gold electrodes used for the experiment had a width of 20 mm each, and a space of 0.5 mm between them.

It is also possible to remove a fullerene sample which has been set from a vacuum vessel, and then to mount the sample in a treatment system as shown in FIG. 1 for electric measurement. It is also possible to expose a fullerene sample to the normal atmosphere, mount the sample which has a degraded conductivity as a result of the exposure in a treatment system, apply an inert gas heating treatment to it, and perform an electric measurement on it in vacuum. An inert gas such as nitrogen is introduced via gas inflow tube 3, and the gas is discharged via gas outflow tube 4. Namely, the gas within vessel 1 is always replaced with the gas introduced via the gas inflow tube. Under this condition, a fullerene film formed on substrate 8 is heated with substrate heater 10. The flow amount of gas and temperature of the fullerene film are controlled by a control system not illustrated here.

For the As Depo measurement, the measurement was performed by passing current in sheer darkness shielded against light, regardless of whether heating was made in the normal atmosphere or in an inert gas atmosphere. A voltage V was applied between the two electrodes arranged on a substrate, and electric current I passed through the electrodes was measured. The electric conductivity σ of a fullerene film was calculated from the equation: σ=I*d/(V*t*W) where W represents the width of the electrode; d the inter-electrode distance; and t the thickness of the fullerene film.

(Heating Treatment in an Inert Gas Atmosphere)

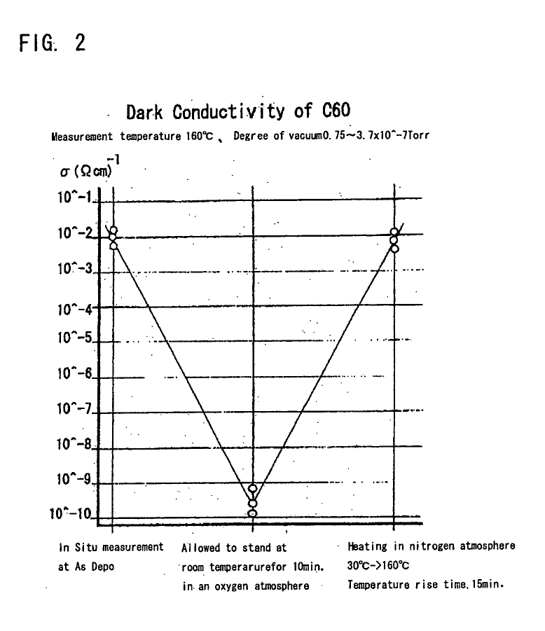

FIG. 2 shows a graph representing the change in conductivity of fullerenes when the inventive nitrogen heating treatment is applied to the fullerenes. The measurement condition consisted of the temperature of 160° C. and degree of vacuum of 0.75 to 3.7×10⁻⁷ Torr. With regard to the conductivity of fullerenes before the heating treatment, the In Situ measurement undertaken immediately after vapor deposition gave a result of 10⁻² (Ωcm)⁻¹. Then, after the fullerenes had been kept in an oxygen atmosphere for 10 minutes, their conductivity shifted to a level ranging from 10⁻¹⁰ (Ωcm)⁻¹ to 10⁻⁹ (Ωcm)⁻¹. Then, the fullerenes were placed in a vessel which was then sealed, and a heating treatment was performed which consisted of heating the fullerenes from 30° C. to 160° C. for 15 minutes while nitrogen was allowed to flow continuously through the vessel. Immediately after the specified temperature was reached, the conductivity of the fullerenes was measured, and it was confirmed from the measurement that the conductivity of the fullerenes recovered to a level (10⁻² (Ωcm)⁻¹) almost equal to the As Depo measurement.

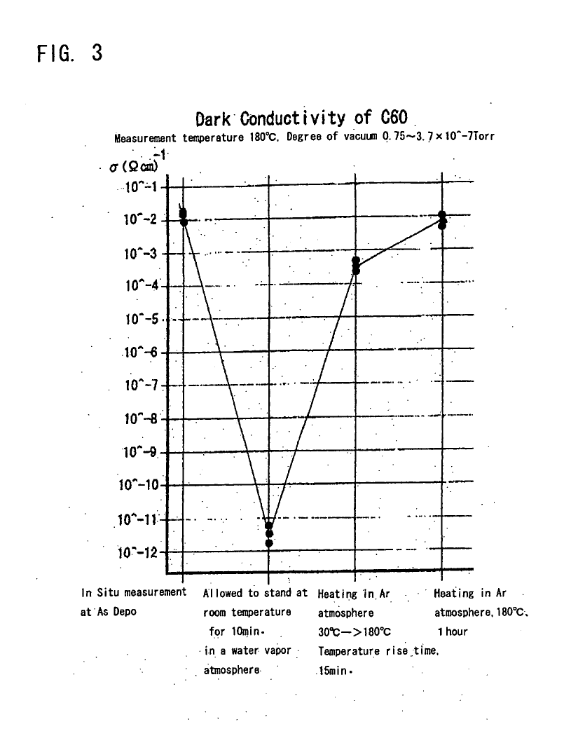

FIG. 3 shows a graph representing the change in conductivity of fullerenes when the inventive argon heating treatment is applied to the fullerenes. The measurement condition consisted of the temperature of 180° C. and degree of vacuum of 0.75 to 3.7×10⁻⁷ Torr. With regard to the conductivity of fullerenes before the heating treatment, the In Situ measurement undertaken immediately after vapor deposition gave a result of 10⁻² (Ωcm)⁻¹. Then, after the fullerenes had been kept in a water vapor atmosphere for 10 minutes, their conductivity shifted to a level ranging from 10⁻¹² (Ωcm)⁻¹ to 10⁻⁹ (Ωcm)⁻¹. Then, the fullerenes were placed in a vessel which was then sealed, and a heating treatment was performed which consisted of heating the fullerenes from 30° C. to 180° C. for 15 minutes while argon was allowed to flow continuously through the vessel. Immediately after the specified temperature was reached, the conductivity of the fullerenes was measured, and it was found that although the conductivity of the fullerenes recovered to 10⁻⁴ (Ωcm)⁻¹, the recovery was still short of the As Depo measurement. Subsequently, while the fullerenes were kept at 180° C., the heating treatment was continued for 1 hour in the argon atmosphere, and the conductivity of the fullerenes was measured. It was confirmed from the measurement that the conductivity recovered to a level approximately equal to the As Depo measurement, 10⁻² (Ωcm)⁻¹.

(Determination of the Concentration of Impurities)

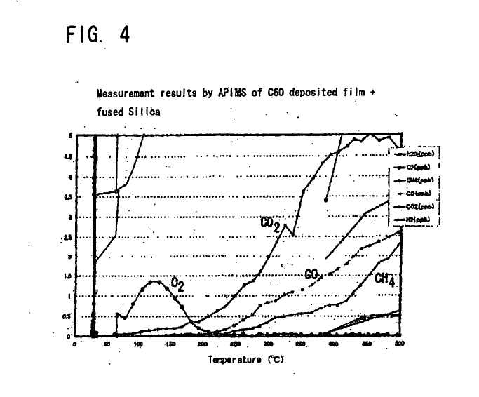

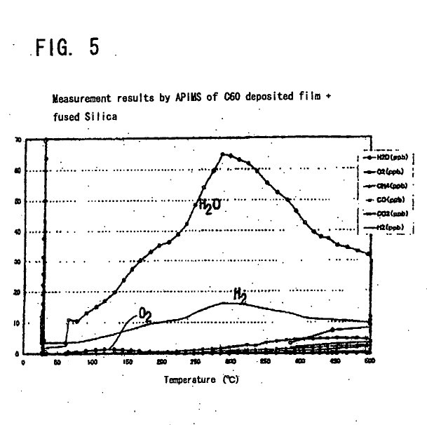

FIGS. 4 and 5 represent the concentration data of impurities detected with an API (atmospheric pressure ionization) mass spectroscopy apparatus. The API mass spectroscopy apparatus is a mass spectroscopy apparatus capable of identifying impurities and determining the concentration of each impurity to a level as low as ppt.

FIGS. 4 and 5 represent the same data, which are, however, plotted along ordinates different in scale. The test sample consisted of a C₆₀ film prepared by vapor deposition, which was then kept in darkness at room temperature for 1 month in a normal atmosphere. For determining the concentration of impurities, the test sample was heated in an argon atmosphere and the temperature was allowed to rise from room temperature to 500° C., and gaseous substances released from the test sample were taken as impurities and determined of their concentrations. FIG. 4 pays a special attention to the change in concentration of oxygen while FIG. 5 to the same change with regard to water.

It can be seen from FIG. 4 that dissociation of oxygen begins at about 100° C., and when the temperature reaches about 200° C., nearly all of oxygen adsorbed to the test sample has been released. In contrast, it can be seen from FIG. 5 that a far larger amount of water is adsorbed to fullerenes as compared with oxygen, and that dissociation of water occurs at 200° C. which is higher than the temperature at which dissociation of oxygen occurs, and dissociation of water is not terminated even when the temperature reaches 500° C.

This will be explained by assuming that water is more easily adsorbed to fullerenes than oxygen and that water requires more energy for dissociation than does oxygen. This assumption is verified by an observation made in a separate experiment: although fullerenes are kept in an oxygen atmosphere, a minute amount of moisture contained in the oxygen atmosphere is more readily adsorbed to fullerenes than oxygen, and thus later when the fullerenes are heated to 200° C., the amount of water contained in the fullerenes is larger than the content of oxygen.

(Condition of Heating Treatment)

A series of experiments consisting of the vapor deposition of fullerenes, maintenance at room temperature, maintenance in darkness, exposure to the normal atmosphere, heating in an inert gas, and measurement of their conductivity were conducted with treatment conditions varied widely according to the experimental protocol as outlined above. The experiment was performed not only on void fullerenes but also on endohedral fullerenes. As a consequence of the experiment, following observations were obtained.

(1) The conductivity of fullerenes is lowered when they have been kept in a normal atmosphere, or in an oxygen atmosphere at room temperature.

(2) No reduction in conductivity of fullerenes is observed when they have been kept in an atmosphere of an inert gas such as nitrogen, Ar or the like at room temperature.

(3) The fullerenes whose conductivity lowers as a result of a treatment as described in paragraph (1) recovers their conductivity after being heated in vacuum.

(4) It is not possible to recover the lowered conductivity of fullerenes observed after the fullerenes have been heated in a normal or oxygen atmosphere to 200° C. or higher by heating the fullerenes in vacuum.

The above is a summary of the previously reported observations reconfirmed by the present inventors. In addition to the above, the present inventors made novel observations as described below.

(5) The conductivity of endohedral fullerenes is lowered when they have been kept in a normal atmosphere, or in an oxygen atmosphere at room temperature.

(6) No reduction in conductivity of endohedral fullerenes is observed when they have been kept in an atmosphere of an inert gas such as nitrogen, Ar or the like at room temperature.

(7) The fullerenes whose conductivity lowers as a result of a treatment as described in paragraph (5) recovers their conductivity after being heated in vacuum.

(8) Even with endohedral fullerenes, it is not possible to recover their lowered conductivity observed after they have being heated in a normal or oxygen atmosphere to 200° C. or higher by heating the fullerenes in vacuum.

For the convenience of description, the term “fullerenes” is used for representing not only void fullerenes but also endohedral fullerenes. The exact definition of fullerenes will be given later.

(9) Recovery of the lowered conductivity of fullerenes, which have been kept in a normal, or oxygen atmosphere at room temperature was achieved by heating the fullerenes in an atmosphere of an inert gas such as nitrogen or Ar. The inert gas suitable for the effect includes any one, or a mixture of two or more chosen from the group comprising nitrogen, Ar, He, Kr, Ne, and Xe. However, recovery of the lower conductivity is achieved only when the fullerenes are heated at 200° C. or higher for 10 sec or longer in an atmosphere of an inert gas as described above. As long as heating is performed while the inert gas in the vessel is continuously replenished by purging, it is possible to recover the lowered conductivity by heating the fullerenes at 100° C. or higher for 10 seconds or longer. In particular, the continuous flow of the inert gas through the vessel at a flow rate that allows the passage of the gas having a volume at least three times as large as that of the vessel for every minute, has a marked effect on the recovery of the lowered conductivity. It was further confirmed that in either case, when heating continues for 10 hours or longer, the recovery of lowered conductivity due to heating would be saturated. When the flow rate of the inert gas is so low that the volume of the gas passed through the vessel for every minute is smaller than the volume three times as large as that of the vessel, the recovery of lowered conductivity will be reduced because then renewed adsorption of oxygen and moisture released by the test sample will occur. On the other hand, raising the flow rate of the gas so high as to allow the volume of the gas passed through the vessel for every minute to be larger than the volume ten times as large as that of the vessel, will pose another problem: heat dissipation from the substrate is emphasized so much that heating of the substrate is disturbed, temperature becomes unstable, and consumption of gas is intensified which leads to the increased production cost.

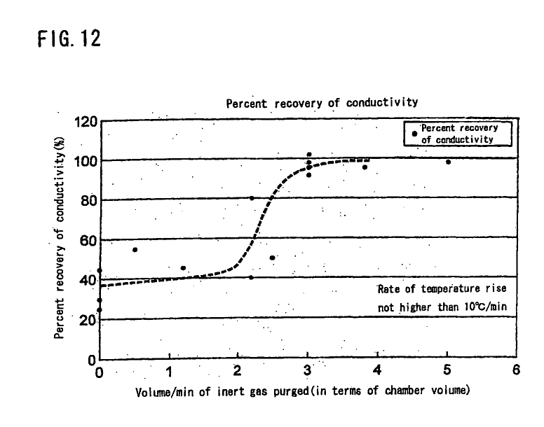

FIG. 12 shows a graph representing the dependency of the recovery of lowered conductivity of fullerenes due to heating treatment on the flow rate of inert gas. In this evaluation experiment, a vessel having a volume of about 17 liters was used. The fullerene film used for the experiment had a thickness of 20 nm to 8 μm. The percent recovery of the conductivity was calculated according to the formula: (σ1−σ0)/σ0×100(%) where al represents the conductivity prior to heating treatment, and σ0 the conductivity after heating treatment. It can be seen from FIG. 12 that when the flow rate of gas is so high as to allow the volume of gas passed through the vessel for every minute to be larger than the volume three times as large as that of the vessel, recovery of the conductivity is markedly enhanced.

(10) Recovery of the conductivity is also markedly enhanced when the gas inflow pipe used for the introduction of the inert gas has an internal wall made of a stainless steel material which receives the coating for protection, on its surface, of a passivity membrane made of chromium oxide, aluminum oxide or metal fluoride, and when the heating vessel or the gas inflow pipe is made of a material which releases gas from its surface at a rate not higher than 1×10⁻¹⁵ (Torr*1/sec*cm²).

(11) With regard to the concentration of impurities in the inert gas, recovery of the conductivity is more marked as the concentration of impurities is lower. The concentration of impurities is preferably 100 ppb or lower, more preferably 10 ppb or lower, and most preferably 100 ppt or lower. In this order, recovery of the conductivity is enhanced.

(12) In particular, when a highly pure inert gas, for example, an inert gas containing oxygen at 10 ppt or lower, and water at 10 ppt or lower, is used as a gas in contact with fullerenes during heating treatment which consists of heating the fullerenes at 300° C. or higher, recovery of the conductivity is enhanced and the conductivity observed is higher than the conductivity of a fullerene film obtained by vapor deposition and determined by As Depo measurement, and thus it is possible by this method to obtain fullerenes whose conductivity is 10⁻¹ (Ωcm)⁻¹ or higher. This is probably because fullerenes themselves used for vapor deposition also contain trace amounts of water and oxygen, which are removed as a result of the inert gas heating treatment.

(13) As far as the removal of impurities is concerned, as the temperature at which the heating treatment occurs is higher, it is more preferred. However, if the temperature of the heating treatment becomes too high, fullerenes themselves will sublimate. In order to reduce the sublimation of fullerenes to a sufficiently low level, it is desirable to maintain the temperature of heat treatment at 700° C. or lower.

(14) Recovery of the conductivity of a test sample was evaluated when the rate of temperature rise during the heating treatment applied to the test sample was varied. The test sample was a fullerene film having a thickness of 0.8 μm. Nitrogen was flowed at a rate to allow the volume of nitrogen passed through the heating vessel for every minute to be three times as large as that of the vessel.

| Temperature | Recovery of | |
|---|---|---|
| rise (° C./min) | conductivity | Condition |
| 40.5 | 59% | 40° C.−> 4 min heating −>202° C. |
| reached | | |
| 6.9 | 98% | 40° C.−> 30 min heating −> 247° C. |
| 6.1 | 96% | 37° C.−> 30 min heating −> 220° C. |
| 1.0 | 98% | 35° C.−> 120 min heating −> 160° C. |
| 42.0 | 74% | 40° C.−> 5 min heating −> 250° C. |
| 22.0 | 69% | 40° C.−> 6 min heating −> 172° C. |
| 17.4 | 92% | 39° C.−> 10 min heating −> 213° C. |

From the above data it can be seen that when the rate of temperature rise is higher than 20° C./min, no marked recovery of the conductivity is observed, whereas when heating occurs slowly, for example, the rate of temperature rise is kept equal to or lower than 20° C./min, recovery of the conductivity becomes remarkable. This is probably because when heating occurs slowly, oxygen and water adsorbed to the surface and interior of a test material will be released outside the test material without being confined to the latter through chemical bondage.

(Adsorption and Dissociation of Impurities)

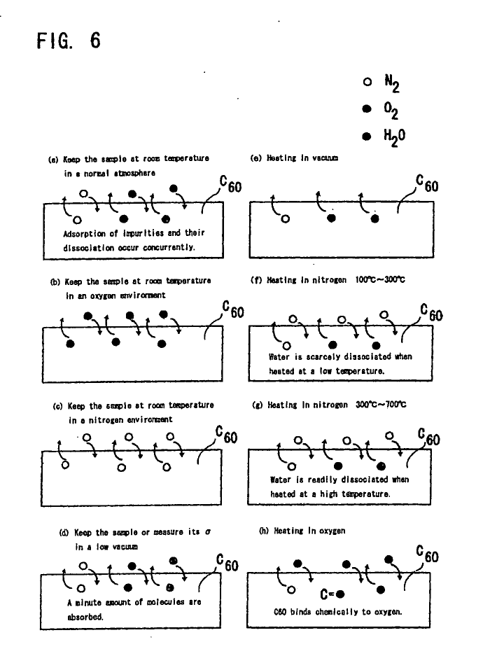

The present inventors estimated a possible mechanism responsible for the adsorption and dissociation of impurities to and from fullerenes based on the observations hitherto obtained. FIGS. 6(a) to 6(h) are a collection of diagrams for explaining the adsorption and dissociation of impurities to and from fullerenes.

It is assumed that impurities adsorbed physically to fullerenes can move about in the fullerenes comparatively freely. It is also assumed that the moving speed of impurities in fullerenes is higher when heated than when kept at room temperature.

As shown in FIG. 6(a), when a test sample is kept in a normal atmosphere at room temperature, its surface is brought in continuous contact with nitrogen, oxygen, and water of the atmosphere, and thus adsorption of impurities to the fullerenes and dissociation of impurities from the fullerenes occur simultaneously and incessantly at the interface between the fullerenes and the atmosphere. Therefore, it is thought that the concentration of impurities residing in the fullerenes is kept at an equilibrium level.

As shown in FIG. 6(b), when a test sample is kept in an oxygen atmosphere, the concentration of oxygen in the atmosphere is so high and the concentration of nitrogen in the atmosphere is so low that when an equilibrium state is reached, the oxygen content of the fullerenes is high as compared with that of nitrogen. If the oxygen atmosphere also contains water if any, a part thereof will be transferred to the fullerenes.

On the other hand, when a test sample is kept in a nitrogen atmosphere as shown in FIG. 6(c), the contents of oxygen and water in the sample is not increased so much as to be equal to the corresponding levels of fullerenes kept under an As Depo state. However, impurities confined in this test sample are comparatively slow in migration and thus it is difficult to completely remove oxygen and water from the sample once they are entrapped in the sample.

When a test sample was kept in a low degree vacuum, its conductivity, when determined by In Situ measurement, was rather low. This is probably because a low degree vacuum permits the presence of a minute amount of impurities within the vessel and part of the impurities, particularly oxygen and water are adsorbed to fullerenes as shown in FIG. 6(d).

When the degree of vacuum is high, dissociation of oxygen and water once adsorbed to fullerenes will occur as a result of heating in vacuum as shown in FIG. 6(e), which will lead to the recovery in conductivity of the fullerenes.

When fullerenes are heated in nitrogen, nitrogen molecules in the vessel replace oxygen and water adsorbed to the fullerenes as shown in FIGS. 6(f) and 6(g), which will lead to the recovery in conductivity of the fullerenes. Particularly, the dissociation of water becomes more marked when the heating temperature is raised to 200° C. or higher, and thus recovery of the conductivity of fullerenes will be greatly enhanced. When a film comprising fullerenes or nanotubes to which a large amount of oxygen or water has been adsorbed, is heated in an inert gas, chemical reactions occur between oxygen and water and the fullerenes or nanotubes, while dissociation of oxygen and water from the surface and interior of the film proceeds. In order to achieve the marked improvement of the conductivity of fullerenes or nanotubes by heating treatment without being disturbed by such chemical reactions, it is preferable to keep the concentration of oxygen or water in the film as low as possible.

Particularly, with regard to fullerenes or nanotubes which contain oxygen at 10¹⁴ molecules/cm³ or lower, and water at 10¹⁶ molecules/cm³ or lower; fullerenes which contain water at 10¹⁶ molecules/cm³ or lower; and fullerenes which, when measured at 27° C., has a conductivity of not lower than 10⁻¹ (Ωcm)⁻¹ but not higher than 10 (Ωcm)⁻¹, or fullerenes which, when measured at 27° C., has a conductivity of not lower than 10⁻¹ (Ωcm)⁻¹ but not higher than 10³ (Ωcm)⁻¹, the marked recovery or improvement of their conductivity will be achieved by heating them in an inert gas. The preferred heating condition consists of heating in an inert gas at a temperature not lower than 200° C. but not higher than 700° C. for a period not shorter than 10 seconds but not longer than 10 hours, or when the heating occurs in a vessel or vessel through which an inert gas is flowed by purging, the preferred heating occurs at a temperature not lower than 100° C. but not higher than 700° C. for a period not shorter than 10 seconds but not longer than 10 hours.

Based on the knowledge obtained from the non-patent document 1, fullerenes were heated in an inert gas while the gas being flowed by purging through a vessel, but the recovery of the conductivity of the fullerenes was not so marked as had been expected. Since nitrogen molecules in contact with the surface of fullerenes are not always replaced by new nitrogen molecules, this is probably because oxygen molecules once dissociated from the fullerenes are adsorbed again to the fullerenes. To avoid such re-adsorption of oxygen, it is important to restrict the flow amount of an inert gas such as nitrogen through a vessel and to incessantly provide a new supply of the inert gas.

A supplementary observation will be given with reference to FIG. 6(h). When heating is performed in an oxygen atmosphere, carbon atoms constituting fullerenes will bind to oxygen chemically. Accordingly, even if the fullerenes are heated in vacuum or in an inert gas, recovery of their conductivity will not be realized because the oxygen will be resistive to dissociation.

(Dependence of the Conductivity of Fullerenes on the Concentration of Impurities Therein)

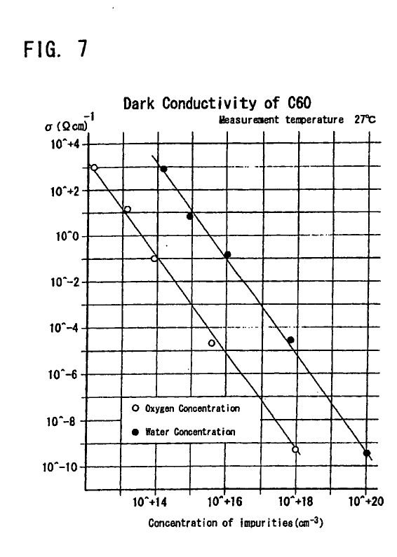

FIG. 7 shows the data representing the correlation of the conductivity of C₆₀ with the concentration of impurities therein. As seen from FIG. 7, the conductivity a correlates negatively with the concentration of oxygen or water contained in fullerenes. However, the conductivity does not depend solely on the concentration of oxygen or water independently of each other. For example, when the concentration of water is high, the conductivity does not become high no matter how much the concentration of oxygen is reduced.

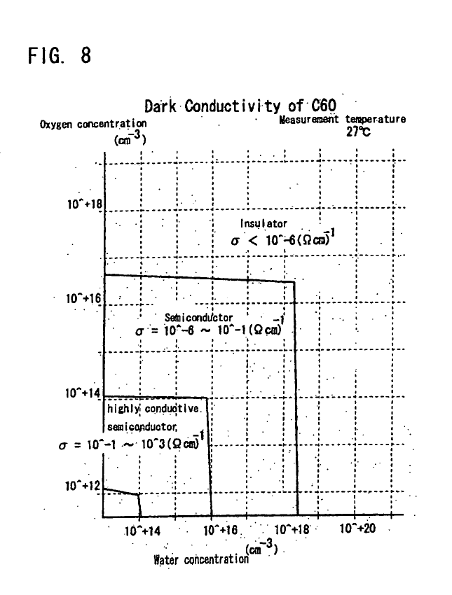

The concentration of oxygen and the concentration of water have a cumulative effect on the conductivity. Taking this relationship into consideration and collecting many relevant data, the graph shown in FIG. 8 was prepared. The coordinate system in FIG. 8, where the ordinate represents the concentration of oxygen in a logarithmic scale, and the abscissa the concentration of water in a logarithmic scale, shows zones where fullerenes act as an insulator (σ<10⁻⁶ (Ω·cm)⁻¹), semiconductor (σ>10⁻⁶ (Ω·cm)⁻¹) and high conductive semiconductor (σ>10⁻¹ (Ωcm)⁻¹).

It can be seen from FIG. 8 that when fullerenes have a concentration of oxygen not higher than 10¹⁶ molecules/cm³ and a concentration of water not higher than 10¹⁸ molecules/cm³, they will have a conductivity falling in the semiconductor zone; and when fullerenes have a concentration of oxygen not higher than 10¹⁴ molecules/cm³ and a concentration of water not higher than 10¹⁶ molecules/cm³, they will have a conductivity falling in the highly conductive semiconductor zone.

To achieve the increased conductivity of fullerenes, it is preferred to keep the concentration of oxygen therein not higher than 10¹⁶ molecules/cm³ and concentration of water not higher than 10¹⁸ molecules/cm³, more preferably keep the concentration of oxygen not higher than 10¹⁴ molecules/cm³ and concentration of water not higher than 10¹⁶ molecules/cm³, and most preferably keep the concentration of oxygen not higher than 10¹² molecules/cm³ and concentration of water not higher than 10¹⁴ molecules/cm³.

(Highly Conductive Fullerenes)

The terms “highly conductive semiconductor zone” and “highly conductive fullerenes” are used herein, although they are not generally used in the prior art, to specifically designate the highly conductive fullerenes having a conductivity of σ>10⁻¹ (Ωcm)⁻¹) which are only produced by the inventive method, because they as organic semiconductors exhibit a far superior conductivity as compared with common semiconductors.

(Passivation)

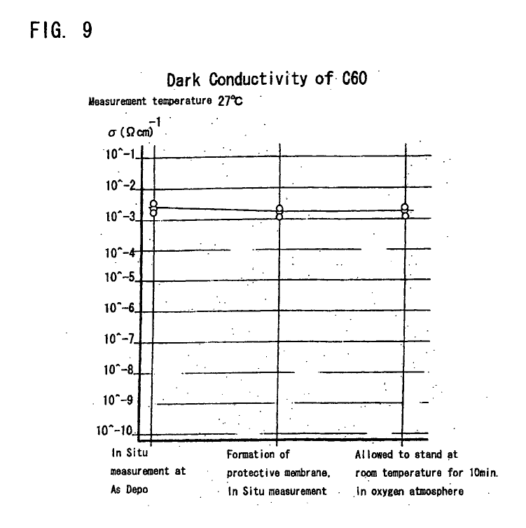

FIG. 9 shows the change in conductivity of fullerenes when the fullerenes receive the coating of a protective membrane (passivation membrane) on its surface. Immediately after a fullerene film having a thickness of 0.4 μm was formed by vapor deposition, nitrogen was passed by purging through a vessel without removing the film from the vessel, and a protective membrane of polyimide was deposited to a thickness of about 2 μm by spin coating on the top of the fullerene film. After the protective membrane was deposited, oxygen was allowed to enter into the vessel, and stay there for 10 minutes. As shown in the figure, no reduction in conductivity is observed. From this it is shown that to prevent the adsorption of oxygen and water to fullerenes, it is effective to recover or improve the conductivity of fullerenes by heating them in an inert gas, and then to form a protective membrane on the surface of the fullerene film. The preventive effect of the passivation membrane against the adsorption of impurities to fullerenes is not only observable in void fullerenes but also in fullerenes at large as will be mentioned later.

The suitable material for the protective membrane includes, in addition to polyimide, SiO₂, Si₃N₄, polyimide, polymethylmethacrylate, polyvinylidenefluoride, polycarbonate, polyvinylalcohol, acryl resin or glass. Formation of the protective membrane may be achieved, in addition to spin coating, by CVD, PVD, spray coating, or dip coating.

(Condition Suitable for the Production of Highly Conductive Fullerenes)

A system was prepared by applying ultra-clean technology as much as possible to the fabrication of a chamber where vapor deposition and measurement will be performed similar to the one shown in FIG. 1 with an aim to minimize the dissociation of oxygen and water from the vacuum vessel itself. A vessel corresponding to vessel 1 of FIG. 1 has its surface coated for protection with a passivation membrane made of chromium oxide; a gas inflow tube corresponding to gas inflow tube 3 is made of a stainless steel and has its internal surface coated with a passivation membrane made of chromium oxide; all-metal valves are so constructed as to minimize redundant species which may cause the stagnation of gas flow; a mass flow control is used; and an adsorption unit equipped with a liquid-nitrogen trap and molecular sieve is installed to remove oxygen and water very marginally present in an inert gas such as nitrogen or argon entering through the gas inflow tube, to thereby produce a ultra-clean inert gas.

It was found by studying fullerenes produced by the above-described method suitable for the production of highly conductive fullerenes that it is possible to deposit a fullerene film having a high conductivity without requiring the heating in an inert gas simply by precipitating fullerenes by vapor deposition. To produce a fullerene film having a high conductivity, it is preferred to employ the following conditions as described below.

(1) The fullerene material should be so pure as to contain carbon at 99.6 wt % or higher.

(2) The vessel for vapor deposition should be made of a stainless steel material, and its internal wall have its surface coated for protection with a passivation membrane made of chromium oxide, aluminum oxide or metal fluoride. Alternatively, the vessel should have an internal wall, which is made of a material that allows the discharge of gas therefrom to be 1×10⁻¹⁵ (Torr*1/sec*cm²) or less.

(3) The degree of vacuum during vapor deposition should be kept at 10⁻⁹ Torr or lower, more preferably 10⁻¹⁰ Torr or lower, most preferably 10⁻¹¹ Torr or lower.

As described above, the system suitable for recovering or improving the conductivity of a material comprising fullerenes or nanotubes by heating the material in an atmosphere of an inert gas should preferably include one that comprises a vessel equipped with a gas inflow tube and gas outflow tube, a heating means, a heating controlling means, and a gas flow controlling means. In addition, the system is preferably so constructed as to allow the heating condition and gas flow condition to be controlled in association, so that the temperature rise during heating, heating temperature, and gas flow can be finely controlled in synchrony.

(Fullerenes)

The production method according to the invention can be applied not only to void fullerenes, but also to any materials that will have a reduced conductivity when they are subject to the adsorption of oxygen and water, and the method is effective for recovering or improving the conductivity of those materials. The method is particularly effective when it is applied to “fullerenes.” The term “fullerenes” used herein includes common fullerenes, endohedral fullerenes, heterofullerenes, chemically modified fullerenes, fullerene oligomers, fullerene polymers, etc. The term “endohedral fullerene” means a spherical carbon molecule entrapping an atom or molecule other than carbon within the hollow of its cage-like shell.

The inventive production method can be applied not only to C₆₀ but also to C₆₀, C₇₀, C₇₆, C₇₈, C₈₂, and C₈₄ that have the same electric properties as does C₆₀, and a mixture thereof, obviously with the same results.

Furthermore, the inventive production method can be applied not only to a fullerene-based film but also to a fullerene containing solid, powder, coating membrane, single crystal, poly-crystal, film, fiber, dopant material, vapor-deposited material, and co-deposited material. When the inventive method is applied for the preparation of such a material, the material will have its conductivity recovered or improved.

Still further, the inventive production method can be applied for the preparation of a nanotube such as a carbon nanotube and a nanotube prepared by the inventive method will have its conductivity recovered or improved.

(Application to Gas Sensor)

Gas adsorption to a fullerene, endohedral fullerenes, or fullerenes, or to a nanotube affects reversibly and sensitively the electric properties of that conjugated carbon system. Based on this phenomenon, it is possible to utilize a fullerene, endohedral fullerenes, or fullerenes, or a nanotube as a highly sensitive gas sensor with a wide dynamic range.

It is possible by using such a sensor to detect the concentration of oxygen and water highly sensitively in a range of 1 ppb to 1000 ppm, with its dynamic range being kept very wide.

The gas to be detected by such a sensor can not include, as far as based on current knowledge, rare gas elements such as He, Ar, etc., and inert gases such as nitrogen, etc., because the adsorption of such a gas to the sensor will not affect the electric properties of the sensor. However, with regard to many other gases, it is possible by using a sensor based on fullerenes or a nanotube to sensitively detect the presence of, in addition to oxygen and water, alcohols, halogen gases, oxidizing gases, reducing gases such as hydrogen, carbon monoxide, nitrogen oxides, etc., and gases that when adsorbed to fullerenes, tend to entrap electrons or holes.

An endohedral fullerene is particularly suitable, among those fullerenes, for the construction of a gas sensor, and it is thus possible by using an endohedral fullerene as a material to produce a highly sensitive gas sensor. In particular, use of a fullerene doped with an alkali metal element, alkali earth metal element, rare earth element, halogen element or V group element will lead to the improved performance of the sensor.

Next, description will be given about the relationship between the concentration of a test gas adsorbed to a sensor body and the concentration of the test gas in an atmosphere in contact with the sensor body. The electric resistance of a test sample varies depending on the concentration of a gas adsorbed to the test sample. When the concentration of the test gas in the atmosphere is higher than the concentration of the test gas adsorbed to the sensor body, the test gas molecules will migrate from the atmosphere to the sensor body (adsorption), and the concentration of the test gas adsorbed will reach a saturation level corresponding to the concentration of the test gas in the atmosphere after a certain time interval. On the contrary, when the concentration of the test gas in the atmosphere is lower than the concentration of the test gas adsorbed to the sensor body, the test gas molecules will migrate from the sensor body to the atmosphere (dissociation), and the concentration of the test gas adsorbed will reach a saturation level corresponding to the concentration of the test gas in the atmosphere after a certain time interval similarly to the above. However, there is a great difference between the speed at which adsorption of a gas occurs and the dissociation speed of the gas: adsorption of a gas reaches a saturation level in a comparatively short period (0.1 to several seconds) while dissociation of the gas is very slow in reaching its saturation level.

It is possible to make a real-time measurement of the concentration of a gas using a sensor body comprising fullerenes, or a nanotube. It is also possible to prepare a highly responsive gas sensor (0.1 to several seconds) by allowing it to have a structure as described below. Namely, the gas sensor includes plural sensor bodies, which will be heated in an inert gas, flowed by purging independently of each other. Prior to use, all the sensor bodies are heated in an inert gas flowed by purging to remove the gas previously adsorbed to the sensor bodies. A first sensor body is used for measuring the concentration of a test gas. Then, at a second timing, a second sensor body is used for measuring the concentration of the test gas. This time, the first sensor body is subjected to the inert gas heating to remove the gas adsorbed to the sensor body. At a third timing, the first sensor body and a third sensor body are used for measuring the concentration of the test gas. This, the second sensor body is subjected to the inert gas heating to remove the gas adsorbed to the sensor body. How many sensor bodies should be prepared may be determined as appropriate depending on the speed of gas dissociation, speed of response, and specified requirement of the task.

When it is required to prepare a highly responsive gas sensor, it is possible to utilize the initial rising phase of electric resistance instead of its saturation phase for the detection of a test gas. When a test gas is adsorbed to a sensor, the electric resistance of the sensor will be increased, and it will reach a saturation level after a certain time interval. The rate at which the electric resistance of the sensor increases before it reaches a saturation level varies depending on the concentration of a test gas adsorbed to the sensor. Namely, when the amount of a test gas adsorbed to the sensor is large, the rate at which the electric resistance of the sensor increases will also be large, while when the amount of a test gas adsorbed to the sensor is small, the rate at which the electric resistance of the sensor increases will also be small. It is possible by utilizing this feature to prepare a gas sensor capable of measuring the highly variable change in concentration of a test gas lasting only for 1 msec to 0.1 second.

The ultra-sensitive real time analysis of gas components performed with atmospheric pressure ionization mass spectroscopy (API/MS) has been attracting attention as a technique indispensable for the plants engaged in the fabrication of state-of-the-art semiconductors. The API/MS is a highly sensitive gas analysis technique that allows the analysis of gas components with a sensitivity 1000 times as high as a conventional gas chromatography-mass spectroscopic machine. However, disadvantageously the mass spectroscopy machine is very bulky and expensive. In contrast, it is possible to analyze gas components in a sample by combining an ionic molecule reaction unit with a sensor body comprising fullerenes including a fullerene, endohedral fullerene, or fullerenes, or a nanotube into a gas sensor, allowing ions derived by ionization from the gas components to be adsorbed to the sensor body, and detecting the change in electric resistance of the sensor body in association with the adsorption of ions. This gas sensor will detect the presence of gas components in a sample and their respective concentrations more sensitively than a conventional gas sensor, which analyzes gas components in a sample by bringing its sensor portion into direct contact with the sample. The ionic molecule reaction unit suitable for the purpose may include a number of commercially available units such as those based on electro-spraying, or on atmospheric pressure chemical ionization. By combining such an ionic molecule reaction unit with a sensor body comprising fullerenes including a fullerene, endohedral fullerene, or fullerenes, or a nanotube, it will be possible to obtain a more compact, low-cost, and portable gas sensor than a conventional gas sensor.

Such a compact, low-cost gas sensor will command wide applications, which will go beyond semiconductor fabrication industries. Specifically, in chemical product plants and nuclear power plants, it will be used as a gas sensor for checking the leak of gas from plumbing systems; in general plants and automobile factories, it will be used for measuring the gas components of exhaust gas from a boiler or an automobile; in air-ports and public facilities, it will be used for checking the possible presence of an explosive, a toxic substance, unlawful chemicals such as narcotics; in general factories it will be used as an aid in the development research of a fuel cell (in the measurement of hydrogen concentration); and in medicine it will be used as an analyzer of the components of gas expired by the patient.

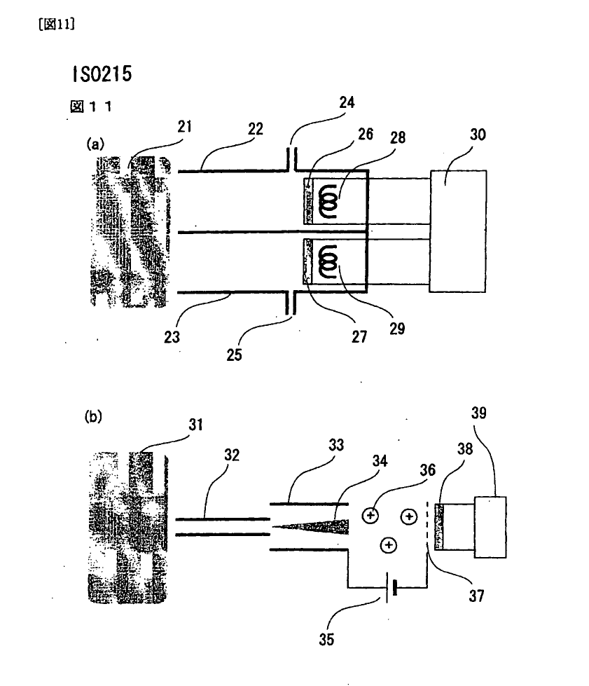

FIG. 11(a) shows a first illustrative example of a gas sensor prepared according to the present invention. This represents a sectional view of the gas sensor with a refresh function capable of determining the concentration of gas on a real time basis. In the particular gas sensor shown in FIG. 11(a), two sensor bodies are depicted in their profiles. However, the sensor may include three or more sensor bodies. The gas sensor comprises gas inflow tubes 22, 23 for introducing a test gas 21 which are separated with a partition wall from each other. Each of sensor bodies 26, 27 is obtained by depositing a film comprising endohedral fullerenes on a substrate, and attaching an electrode for resistance measurement to each side of the film. The gas introduced through gas inflow tubes 22, 23 is brought into contact with sensor bodies 26, 27 so that the gas can be detected with sensor bodies 26, 27 independently of each other. When the gas is adsorbed to the sensor body, the electric resistance of the sensor body is changed. This change of electric resistance is measured by a metering device 30 where the measurement data is processed to be converted into a gas concentration data. It is possible to quickly eliminate the portion of the gas adsorbed to the sensor body by introducing nitrogen via nitrogen inflow tubes 24, 25, and activating heaters 28, 29 at the same time. In the manner as described above, it is possible to measure the concentration of a gas on a real time basis by using a gas sensor comprising plural sensor bodies.

FIG. 11(b) shows a second illustrative example of a gas sensor prepared according to the present invention. This represents a gas sensor equipped with a unit for ionizing a test gas by atmospheric pressure ionization. A test gas 31 is introduced into the ionization unit through a gas inflow tube 32. Heating of a flow 34 of the test gas occurs when the flow passes through the hollow of a tubular heater 33, and the gas flow is converted into gas ions 36 under the influence of an electric field formed between the wall of the heater and a grid electrode 37 by a power supply 35. A portion of the gas ions is adsorbed to a sensor body 38, which produces a change in the electric resistance of the sensor body to be detected by a resistance measurement meter 39 where the measurement data is processed to be converted into a gas concentration data.

### EXAMPLES

The present invention will be described below with reference to examples. However, the present invention should not be limited in any way to those examples.

### Example 1

### Vapor Deposition in an Ultra-Clean Environment

An environment suitable for manufacturing a fullerene film according to the above-described condition appropriate for the production of highly conductive fullerenes was prepared using a system as shown in FIG. 1 where the degree of vacuum within vessel 1 was made 5×10⁻¹⁰ Torr (6.65×10⁻⁸ Pa). According to an API-MS machine connected to the vessel 1, it was found that the concentration of water at a site where a fullerene film would be formed was 3 ppt. A 50 mg of fullerenes C₆₀ (Tokyo Chemical Industry) was placed in a molybdenum-made boat for vapor deposition, and the boat was heated at 500° C. for 1 hour so that a fullerene film having a thickness of about 0.4 μm was deposited on a substrate 8. Under an As-Depo state where the substrate temperature was 82° C., the measurement was made by applying a voltage of 2V between two terminals which resulted in the passage of current of 1.1 mA, and the conductivity was found to be 0.34 (Ωcm)⁻¹. Then, the vessel was slowly cooled to room temperature or 27° C. where the conductivity was found to be 0.11 (Ωcm)⁻¹.

### Example 2

### Vapor Deposition in an Ultra-Clean Environment

An environment suitable for manufacturing a fullerene film according to the above-described condition appropriate for the production of highly conductive fullerenes was prepared using a system as shown in FIG. 1. The vessel or chamber was baked at 150° C. for one week. As a result, the degree of vacuum within vessel 1 was found to be 10⁻¹¹ Torr. According to an API-MS machine connected to the vessel 1, it was found that the concentration of water at a site where a fullerene film would be formed was 1 ppt or less. A 50 mg of fullerenes C₆₀ (Tokyo Chemical Industry) was placed in a molybdenum-made boat for vapor deposition, and the boat was heated at 470° C. for 30 minutes so that a fullerene film having a thickness of about 0.1 μm was deposited on a substrate 8. Under an As-Depo state where the substrate temperature was 74° C., the measurement was made by applying a voltage of 0.2V between two terminals which resulted in the passage of current of 2.6 mA, and the conductivity was found to be 32.5 (Ω·cm)⁻¹. Then, the vessel was slowly cooled to room temperature or 27° C. where the conductivity was found to be 10.2 (Ωcm)⁻¹.

### Example 3

### Recovery of Conductivity Via Co-Deposition and Inert Gas Heating in an Ultra-Clean Environment

An environment suitable for manufacturing a co-deposited film comprising fullerenes according to the above-described condition appropriate for the production of highly conductive fullerenes was prepared using a system as shown in FIG. 1. The vessel or chamber was baked at 150° C. for one week. As a result, the degree of vacuum within vessel 1 was found to be 10⁻¹¹ Torr. According to an API-MS machine connected to the vessel 1, it was found that the concentration of water at a site where a fullerene film would be formed was 1 ppt or less. A 50 mg of fullerenes C₆₀ (Tokyo Chemical Industry) and 50 mg of copper phthalocyanine were placed in a molybdenum-made boat for vapor deposition, and the boat was heated at 470° C. for 30 minutes so that a fullerene/copper phthalocyanine film having a thickness of about 0.1 μm was deposited on a substrate 8. Under an As-Depo state where the substrate temperature was 74° C., the measurement was made by applying a voltage of 0.4V between two terminals which resulted in the passage of current of 10.4 mA, and the conductivity was found to be 63.1 (Ωcm)⁻¹. Then, the vessel was slowly cooled to room temperature or 27° C. where the conductivity was found to be 20.4 (Ωcm)⁻¹.

Later, nitrogen gas was allowed to enter via an adsorption unit equipped with a molecular sieve into the chamber to regain a normal atmospheric pressure. The sample was transferred via a passage with a road-lock to a separate chamber. Oxygen gas was allowed to pass continuously for 10 minutes through the chamber where the sample was settled. Then, the sample was returned to the original chamber. Next, while nitrogen gas was allowed to flow through the chamber, the conductivity of the sample was measured and found to be 4×10⁻⁸ (Ωcm)⁻¹. While nitrogen gas was flowed as before, voltage was applied to a ceramic heater upon which the sample was fixed to heat it. When the heater was activated for 15 minutes, the sample was heated to 160° C. where the measurement was made and the conductivity of the sample was found to be 15.2 (Ωcm)⁻¹ a value close to the one prior to the oxygen exposure.

The combination of fullerenes with another element in the formation of a film can occur in two manners: one is the formation of a co-deposited film, and the other is the formation of a laminated film comprising a fullerene layer and a layer of another element. The evaluation result given above is only concerned with a co-deposited film. However, it was found that the production method of the invention could successfully recover the lowered conductivity for a lamination film as well.

### Example 4

### Recovery of the Conductivity of a Fullerene Film Left in Oxygen Atmosphere

An environment suitable for manufacturing a fullerene film according to the above-described condition appropriate for the production of highly conductive fullerenes was prepared using a system as shown in FIG. 1. The degree of vacuum within vessel 1 was found to be 5×10⁻¹⁰ Torr. According to an API-MS machine connected to the vessel 1, it was found that the concentration of water within vessel 1 was 3 ppt.

A 50 mg of fullerenes C₆₀ (Tokyo Chemical Industry) was placed in a molybdenum-made boat for vapor deposition, and the boat was heated at 500° C. for 1 hour so that a fullerene film having a thickness of about 0.4 μm was formed on a substrate 8 fixed onto a ceramic heater. Under an As-Depo state where the substrate temperature was 82° C., the measurement was made by applying a voltage of 2V between two terminals which resulted in the passage of current of 1.1 mA, and the conductivity was found to be 0.34 (Ωcm)⁻¹. Then, the vessel was slowly cooled to room temperature or 27° C. where the conductivity was found to be 0.11 (Ωcm)⁻¹.

Later, nitrogen gas was allowed to enter via an adsorption unit equipped with a molecular sieve into the chamber to regain a normal atmospheric pressure. The sample was transferred via a passage with a road-lock to a separate chamber. Oxygen gas was allowed to pass continuously for 10 minutes through the chamber where the sample was settled. Then, the sample was returned to the original chamber. Next, while nitrogen gas was allowed to flow through the chamber, the conductivity of the sample was measured and found to be 2×10⁻⁹ (Ωcm)⁻¹. While nitrogen gas was flowed as before, voltage was applied to the ceramic heater upon which the sample was fixed to heat it. When the heater was activated for 15 minutes, the sample was heated to 160° C. where the measurement was made and the conductivity of the sample was found to be 0.1 (Ωcm)⁻¹ a value close to the one prior to the oxygen exposure.

### Example 5

### Recovery of the Conductivity of a Fullerene Film Left in Normal Atmosphere

An environment suitable for manufacturing a fullerene film according to the above-described condition appropriate for the production of highly conductive fullerenes was prepared, and the degree of vacuum was found to be 0.75×10⁻⁷ Torr.

A 50 mg of fullerenes C₆₀ (Tokyo Chemical Industry) was placed in a molybdenum-made boat for vapor deposition, and the boat was heated at 500° C. for 1 hour so that a fullerene film having a thickness of about 0.4 μm was formed on a substrate 8 fixed onto a ceramic heater. Under an As-Depo state where the substrate temperature was 80° C., the measurement was made and the conductivity was found to be 0.06 (Ωcm)⁻¹. Then, the vessel was slowly cooled to room temperature or 27° C. where the conductivity was found to be 0.02 (Ωcm)⁻¹.

Later, argon gas was allowed to enter via an adsorption unit equipped with a molecular sieve into the chamber to regain a normal atmospheric pressure. The sample was transferred via a passage with a road-lock to a separate chamber. Oxygen gas was allowed to pass continuously for 10 minutes through the chamber where the sample was settled. Then, the sample was returned to the original chamber. Next, while nitrogen gas was allowed to flow through the chamber, the conductivity of the sample was measured and found to be 4.2×10⁻¹¹ (Ωcm)⁻¹. While argon gas was flowed as before, voltage was applied to the ceramic heater upon which the sample was fixed to heat it. When the heater was activated for 15 minutes, the sample was heated to 160° C. where the measurement was made and the conductivity of the sample was found to be 0.0096 (Ωcm)⁻¹. Heating was further continued at 180° C. for 1 hour where the conductivity was found to be 0.05 (Ωcm)⁻¹.

### Example 6

### Improvement of Conductivity of a Fullerene Film by Inert Gas Heating

An environment suitable for manufacturing a fullerene film according to the above-described condition appropriate for the production of highly conductive fullerenes was prepared, and the degree of vacuum was found to be 3.1×10⁻⁷ Torr.

A 50 mg of fullerenes C₆₀ (Tokyo Chemical Industry) was placed in a molybdenum-made boat for vapor deposition, and the boat was heated at 500° C. for 1 hour so that a fullerene film having a thickness of about 0.4 μm was formed on a substrate 8 fixed onto a ceramic heater. Under an As-Depo state where the substrate temperature was 80° C., the measurement was made and the conductivity was found to be 0.03 (Ωcm)⁻¹. Then, the vessel was slowly cooled to room temperature or 27° C. where the conductivity was found to be 0.01 (Ωcm)⁻¹.

Later, the chamber was baked at 150° C. for 4 days. On day 4 of baking, the measurement was made and it was found that the conductivity of the test film lowered to 0.0008 (Ωcm)⁻¹. On completion of baking, the chamber was cooled to 30° C. over 1 day. The degree of vacuum was then 2×10⁻¹¹ Torr. Nitrogen gas was allowed to enter via an adsorption unit equipped with a molecular sieve into the chamber to regain a normal atmospheric pressure. While nitrogen gas was allowed to flow as before, voltage was applied to a ceramic heater upon which the sample was fixed to heat it.

When the heater was activated for 25 minutes, the sample was heated to 303° C. where the measurement was made and the conductivity of the sample was found to be 0.76 (Ωcm)⁻¹. Then, the vessel was slowly cooled to room temperature or 28° C. where the conductivity was found to be 0.12 (Ωcm)⁻¹ which was higher than the value obtained at the As-Depo state.

### Example 7

In this example, the experimental set-up was the same as in Example 1 except that the degree of vacuum of vessel was made 10⁻¹¹ Torr. In this example, the test sample exhibited a higher conductivity than in Example 1.

### INDUSTRIAL APPLICABILITY

As described above, fullerenes and a nanotube prepared according to the invention and the inventive method for the production thereof will greatly enhance the conductivity of organic materials, and contribute to the improved performance of organic semiconductor devices, and thus be particularly useful in the field of electronics.

1. Fullerenes, which contain oxygen at 10¹⁴ molecules/cm³ or less, and water at 10¹⁶ molecules/cm³ or less.

2. Fullerenes, which contain water at 10¹⁶ molecules/cm³ or less.

3. Fullerenes, which have an electric conductivity of 10⁻¹ (Ωcm)⁻¹ or higher, and 10 (Ωcm)⁻¹ or lower when measured at 27° C.

4. Fullerenes, which have an electric conductivity of 10⁻¹ (Ωcm)⁻¹ or higher, and 10³ (Ωcm)⁻¹ or lower when measured at 27° C.

5. The fullerenes as claimed in claim 1, which are C₆₀, C₇₀, C₇₆, C₇₈, C₈₂, or C₈₄, or a mixture thereof.

6. A nanotube, which contains oxygen at 10¹⁴ molecules/cm³ or less, and water at 10¹⁶ molecules/cm³ or less.

7. A nanotube, which contains water at 10¹⁶ molecules/cm³ or less.

8. A solid body, powder, coating membrane, single crystal, poly-crystal, film, fiber, dopant material, vapor-deposited material, or co-deposited material which contains fullerenes as claimed in claim 1.

9. A transistor, solar battery, fuel cell, organic EL, sensor, or resistance, which incorporates fullerenes as claimed in claim 1.

10. A method of producing fullerenes or a nanotube which comprises heating fullerenes as claimed in claim 1 at a temperature not lower than 200° C. and not higher than 700° C. in an inert gas for a period not shorter than 10 seconds and not longer than 10 hours.

11. A method of producing fullerenes or a nanotube which comprises heating fullerenes as claimed in claim 1 at a temperature not lower than 100° C. and not higher than 700° C. for a period not shorter than 10 seconds and not longer than 10 hours in an inert gas within a vessel while the inert gas is being purged from the vessel.

12. A method of producing fullerenes or a nanotube which comprises heating fullerenes or a nanotube at a temperature not lower than 100° C. and not higher than 700° C. for a period not shorter than 10 seconds and not longer than 10 hours in an inert gas within a vessel having a volume of V liter while the inert gas is being continuously flowed at a rate not lower than 3V liter/min and not higher than 10V liter/min.

13. A method of producing fullerenes or a nanotube which comprises heating fullerenes or a nanotube at a temperature not lower than 100° C. and not higher than 700° C. for a period not shorter than 10 seconds and not longer than 10 hours while the heating is allowed to proceed at a rate not higher than 20° C./min.

14. A method of producing fullerenes or a nanotube as claimed in claim 10, wherein the fullerenes are C₆₀, C₇₀, C₇₆, C₇₈, C₈₂, or C₈₄, or a mixture thereof.

15. A method of producing fullerenes or a nanotube as claimed in claim 10, wherein the inert gas comprises a gas selected from the group comprising pure nitrogen, Ar, He, Kr, Ne, and Xe, and a mixture thereof.

16. A method of producing fullerenes or a nanotube as claimed in claim 10, wherein the inert gas environment in contact with the fullerenes or the nanotube contains oxygen at 10 ppb or lower, and water at 10 ppb or lower.

17. A method of producing fullerenes or a nanotube as claimed in claim 10, wherein the vessel or the tube through which an inert gas is introduced into the vessel has an internal wall made of a stainless steel material which receives, on its surface, the protective coating of a passivity membrane made of chromium oxide, aluminum oxide or metal fluoride.

18. A method of producing fullerenes or a nanotube as claimed in claim 10, wherein the vessel or the tube through which an inert gas is introduced into the vessel is made of a material which releases gas from its surface at a rate not higher than 1×10⁻¹⁵ (Torr*1/sec*cm²).

19. A method of producing an organic device which comprises preparing a film made of fulleres or a nanotube produced by a method as claimed in claim 10, and forming a protective film made of SiO₂, Si₃N₄, polyimide, polymethylmethacrylate, polyvinylidenefluoride, polycarbonate, polyvinylalcohol, acryl resin or glass by CVD, PVD, spin coating, spray coating, or dip coating.

20. A deposited film made of fullerenes or a nanotube which is deposited, using fullerenes having a carbon content not lower than 99.6 wt %, in a vacuum having a degree of vacuum not higher than 10⁻⁹ Torr within a vacuum vessel which has an internal wall made of a stainless steel material receiving, on its surface, the protective coating of a passivity membrane made of chromium oxide, aluminum oxide or metal fluoride.

21. A deposited film made of fullerenes or a nanotube which is deposited, using fullerenes having a carbon content not lower than 99.6 wt %, in a vacuum having a degree of vacuum not higher than 10⁻¹¹ Torr within a vacuum vessel with an internal wall which releases gas from its surface at a rate not higher than 1×10⁻¹⁵ (Torr*1/sec*cm²).

22. A method of producing a deposited film made of fullerenes or a nanotube which comprises using fullerenes having a carbon content not lower than 99.6 wt %, and depositing the film in a vacuum having a degree of vacuum not higher than 10⁻⁹ Torr within a vacuum vessel with an internal wall made of a stainless steel material which receives, on its surface, the protective coating of a passivity membrane made of chromium oxide, aluminum oxide or metal fluoride.

23. A method of producing a deposited film made of fullerenes or a nanotube which comprises using fullerenes having a carbon content not lower than 99.6 wt %, and depositing the film in a vacuum having a degree of vacuum not higher than 10⁻¹¹ Torr within a vacuum vessel having an internal wall which releases gas from its surface at a rate not higher than 1×10⁻¹⁵ (Torr*1/sec*cm²).

24. A system for producing fullerenes or a nanotube which comprises a vessel equipped with a gas inflow port and a gas outflow port, a heating means, a heating control means, and a gas flow control means, and which can control both the heating condition and the gas flow condition in association.

25. A gas sensor using, as a sensor body, fullerenes as claimed in claim 1.

26. A gas detection method for checking the presence of a gas or determining its concentration by monitoring the change in resistance of fullerenes as claimed in claim 1.
